(19) United States
(12) Patent Application Publication
(10) Pub. No.: US 2025/0257839 A1
(43) Pub. Date: Aug. 14, 2025

(54) METHOD OF PRODUCING ANTI-SCALING AND ANTI-GALLING COATING ON AN INTERNAL SURFACE OF A TUBULAR MEMBER

(71) Applicant: Baker Hughes Oilfield Operations LLC, Houston, TX (US)

(72) Inventors: Zhihui Zhang, Katy, TX (US); Emerson Nunez Moran, Cypress, TX (US); Fernando Kirnbauer, Katy, TX (US); Nitin Bedi, Sugar Land, TX (US)

(21) Appl. No.: 18/436,735

(22) Filed: Feb. 8, 2024

(51) Int. Cl. F16L 58/14; C23C 16/26; C23C 16/50; C23C 28/00; C25D 3/08; C25D 5/00; F16L 58/08; F16L 58/10

(52) U.S. Cl. CPC F16L 58/14; C23C 16/26; C23C 16/50; C23C 28/322; C23C 28/343; C25D 3/08; C25D 5/605; C25D 5/623; F16L 58/08; F16L 58/10

(57) ABSTRACT

A method of coating an internal surface of a tubular member includes: forming a sublayer on the internal surface of the tubular member, the sublayer including a chromium sublayer, a polymer sublayer containing electrically conductive or semi-conductive particles, or a diamond-like carbon sublayer containing an undoped diamond-like carbon material; disposing a hydrophobic layer on the sublayer via a plasma-assisted chemical deposition thereby forming the coating on the internal surface of the tubular member, the hydrophobic layer including a doped diamond-like carbon material, and the doped diamond-like carbon material containing an amorphous diamond-like carbon doped with Si and optionally at least one of F, Co, Cr, W, or Ti.

### BACKGROUND

Many articles used in industry are exposed to harsh environments. For example, tools used in a wellbore or other downhole environment in the oil and gas industry are often exposed to corrosive or oversaturated fluids, which may cause hard scales of inorganic or organic compounds such as CaCO₃, BaSO₄, CaSO₄, SrSO₄, asphaltene, an others to build up on the surfaces of the articles. Such precipitation can occur in pipelines, separators, and other equipment Once deposited, scales can interfere with the normal function of the articles and cause disruption to the system and/or process in which the articles are used and may necessitate repairs or replacements. Accordingly, a method of preventing scale-related fouling or lengthening equipment uptime through scale minimization is continuously sought.

### BRIEF DESCRIPTION

A method of coating an internal surface of a tubular member includes: forming a sublayer on the internal surface of the tubular member, the sublayer including a chromium sublayer, a polymer sublayer containing electrically conductive or semi-conductive particles, or a diamond-like carbon sublayer containing an undoped diamond-like carbon material; disposing a hydrophobic layer on the sublayer via a plasma-assisted chemical deposition thereby forming the coating on the internal surface of the tubular member, the hydrophobic layer including a doped diamond-like carbon material, and the doped diamond-like carbon material containing an amorphous diamond-like carbon doped with Si and optionally at least one of F, Co, Cr, W, or Ti. A coating formed from such a method is also disclosed.

The above described and other features are exemplified by the following Figures, Detailed Description, and Examples.

### BRIEF DESCRIPTION OF THE DRAWINGS

Refer now to the drawings, which are exemplary, not limiting, and wherein like elements are numbered alike:

FIG. 1 is a cross-sectional view of a coated internal surface of a tubular member according to prior art;

FIG. 2 is a scanning electron microscopic (SEM) image showing a textured surface of a dense chromium sublayer;

FIG. 3 is a schematic cross-sectional view of a coated internal surface of a tubular member according to an embodiment of the disclosure;

FIG. 4 is a schematic cross-sectional view of a coated internal surface of a tubular member according to another embodiment of the disclosure;

FIG. 5 is a SEM image showing a coating including a hydrophobic layer and a dense chrome sublayer disposed on an internal surface of a tubular member;

FIG. 6A shows the contact angle (degree) of a diamond-like carbon (DLC) coating without any sublayer, FIG. 6B shows the contact angle (degree) of a coating including a DLC layer disposed on a dense chromium sublayer, and FIG. 6C shows the contact angle (degree) of a coating including a DLC layer disposed on a polymer sublayer;

FIG. 7A and FIG. 7B illustrate the indentation test results of a DLC coating without any sublayer and a DLC coating with a sublayer disposed on an internal surface of a tubular member respectively, demonstrating the improved adhesion of the coating including both the DLC layer and the sublayer; and

FIG. 8 is a graph of the weight of scale deposition (gram, g) on a doped DLC, a DLC without doping, and a bare metal.

### DETAILED DESCRIPTION

A DLC coating can impart hydrophobicity to a surface, and a hydrophobic surface can stay easily clean. DLC coatings can be formed via a plasma enhanced chemical vapor deposition. However, when the internal surface of a tubular member is exposed to a plasma for a long period of time with the DLC coating build-up, the deposited coating can start to discharge as a result of combination of the hollow cathode effect and the surface becoming less conductive, which can cause defects and non-continuity of the coating.

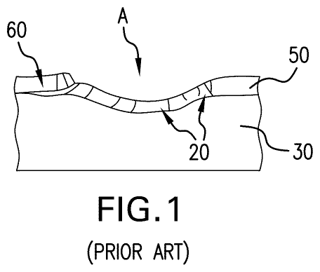

In addition, a thick coating (e.g. over 0.5 micron) is desirable from the mechanical perspective such as the anti-galling and anti-corrosion resistance. However, when the DLC coating is too thick, internal stress can accumulate at the interface of the coating and the substrate. As shown in FIG. 1, when a relatively thick hydrophobic DLC coating (50), for example, a hydrophobic DLC coating with a thickness of greater than 0.5 micron is coated on an internal surface of a tubular member (30), the coating can delaminate (60) and/or generate cracks (20) when a load (A) is applied to the coating (50).

The inventors have discovered a new and cost-effective method of coating an internal surface of a tubular member. The coating produced from such a method is hydrophobic, anti-scaling, galling resistant, and corrosion resistant. As used herein, a hydrophobic coating or layer refers to a coating or layer with a water contact angle of greater than 90°.

The method comprises disposing a sublayer on an internal surface of a tubular member, and disposing a hydrophobic layer on the sublayer. The sublayer includes a chromium sublayer, or a polymer sublayer comprising a polymer and electrically conductive or semi-conductive particles. The sublayer can also be a DLC sublayer with a composition that is different from the DLC in the hydrophobic layer. The hydrophobic layer comprises a doped DLC material. The doping element that imparts the hydrophobicity can include Si and F. Other elements such as Co, Cr, W, Ti can also be added to increase the hydrophobicity and/or to reduce the internal stress.

The chromium sublayer can be disposed on an internal surface of a tubular member via an electrochemical process. Preferably, the sublayer is deposited through a thin dense chrome plating (TDC) process, which is applied at a much slower rate compared to the traditional hard chrome plating. The electrocoating process allows the chromium element of the chromium electrolytic solution to permeate the surface profile of the substrate, resulting a strong adhesion and a crack-free, continuous and dense sublayer. The chromium sublayer does not chip, flake, crack, peel, or separate from the substrate on the standard ASTM bend tests. The TDC sublayer can also present a micro-nodular surface finish.

Prior to any electrochemical deposition, the internal surface of the tubular member can be pre-treated to remove contaminations such as grease, dirt, and debris. Surfactants, solvents, detergents, alkaline cleaners, diphase cleaners, emulsion cleaners, or other suitable cleaners known in the art may be used. Vapor degreasing, dry vapor honing, electrolytic cleaning, ultrasonic cleaning, vibratory cleaning, hydroblasting, vapor blasting, or glass bead blasting can also be used to clean the internal surface to be coated. The cleaned surface must be free of oil, grease, oxides, sulfides, scale, and soils. A surface texture such as a nodular structure can be created by removing the surface material during the pre-treatment process.

The cleaned internal surface can then be exposed to a chromium electrolytic solution containing chromic acid, which can be formed when chromium trioxide (CrO₃) is dissolved in water. The electrolytic solution can further include a catalyst such as sulfuric acid. During the electrochemical deposition, the chromium in the hexavalent state is reduced to chromium metal due to the catalytic effect of sulfate ions. Optionally, fluorides and/or fluorosilicates can also be used as the catalyst in the electrolytic solution. More than one catalyst can be used. Known additives can also be included in the electrolytic solution.

During the electrochemical deposition process, the chromium electrolytic solution can have a temperature below 65° C., for example from room temperature to 65° C. The temperature of the electrolytic solution is maintained at the target temperature range during the process of forming the chromium sublayer.

Exposing the internal surface of the tubular member can include filling the tubular member with the chromium electrolytic solution or immersing the tubular member in a container that holds the chromium electrolytic solution. The surfaces that are not intended to be coated with any chromium can be masked if needed before the tubular member is exposed to the chromium electrolytic solution.

Once the internal surface of the tubular member reaches the temperature of the chromium electrolytic solution, a current is applied to the chromium electrolytic solution for a period of time until a dense chromium layer attains the target thickness.

The sublayer deposited through TDC process has greater density and hardness as compared to a sublayer formed from traditional hard chrome plating. The TDC chromium sublayer can achieve nearly fully density with greater than 98 wt % or greater than 99 wt % of chromium metal as compared to the 80 to 90% chromium prepared with traditional hard chrome plating. The chromium sublayer is dense and can have a porosity of less than 5%, less about 1%, or less than 0.1%. Preferably, the chromium sublayer is free of pores and/or cracks. The crack-free sublayer provides prolonged corrosion protection.

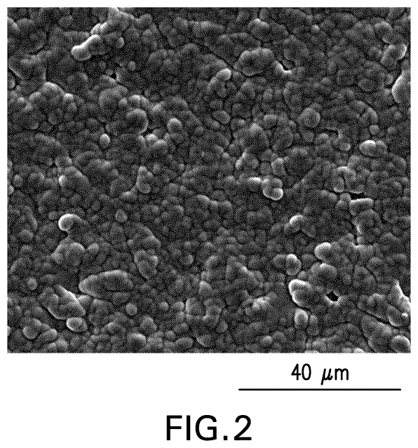

The chromium sublayer can have a surface with microstructures, for example nodules as shown in FIG. 2. The chromium sublayer can promote the bonding between the sublayer and the hydrophobic layer, for example, by forming composition gradient transition chromium carbide layer between the sublayer and the hydrophobic layer reducing the residual stress of the hydrophobic layer. In addition, the surface texture of the chromium sublayer can also improve the hydrophobicity of the coating.

The chromium sublayer can also have outstanding adhesive characteristics with the internal surface of the tubular member. Illustratively, the chromium sublayer may form a lasting bond with the internal surface of the tubular member by permeating the surface porosity of the internal surface of the tubular member.

The chromium sublayer can have a thickness of about 1.2 μm to about 10 μm, preferably about 1.2 μm to about 5 μm, and more preferably about 1.2 μm to about 3.8 μm.

When the sublayer is a polymer layer, the method comprises forming the polymer sublayer by dip coating, air spray coating, airless spray coating, fusion bonding, brush or roller application, or other coating techniques. The surface preparation may include a grit blasting procedure to create a nodular pattern to increase the anchoring strength and water contact angle. The coating is preferably applied by a compressed air or airless spray system. In an air spray coating method, a highly pressurized air or a compressed air, created by a compressor, atomizes the fluid being sprayed and delivers it to the inner surface of the tubular member. In an airless spray coating, the coating composition is atomized, or broken up into small droplets without the use of compressed air. Instead, the coating composition is pumped under high pressure through a spray tip, then separates into very small droplets that form the spray pattern. Dipping can be used for small parts. After the coating is dried, the coating can be further cured at elevated temperatures between about 200 and about 400° F. The coating composition used can include a polymer and electrically conductive or semi-conductive particles. Optionally the coating composition also includes an organic solvent.

The polymer can include at least one of an epoxy, a phenolic resin, or an epoxy phenolic resin. As used herein, an epoxy refers to a cured product of an epoxide that contains one or more epoxide groups. The epoxy can be formed from at least one of an aliphatic epoxide such as butanediol diglycidyl ether, a bisphenol epoxide such as bisphenol-A diglycidyl ether (CAS #1675-54-3) and/or bisphenol-F diglycidyl ether, or a novolac epoxide such as phenol-formaldehyde polymer glycidyl ether (CAS #28064-14-4). The curing agent includes an active group that can react with an epoxy group. Examples of such an active group include amino groups and acid anhydride groups. In an aspect the curing agent is at least one of an aliphatic amine or an aromatic amine.

Phenolic resin, also known as phenolic formaldehyde resin, is a synthetic resin produced from the polymerization of a phenol (C₆H₅OH), an alkyl-substituted phenol, a halogen-substituted phenol, or a combination thereof, and a formaldehyde compound such as formaldehyde (CH₂C═O). The phenolic resin can include repeating units such as —[(C₆H₃OH)—CH₂]—.

Epoxy phenolic resin is phenolic resin modified at the phenolic hydroxyl group to include an epoxide functional group such as —CH₂—(C₂H₃O), where —(C₂H₃O) is a three-membered epoxide ring. The added functionality of the phenolic resin increases the ability for the resin to crosslink, creating a stronger polymer with high resistivities.

As used herein, electrically conductive and semi-conductive particles refer to particles having an electrical conductivity of 1-1000 Simens per centimeter (S/cm). The specific electrically conductive or semi-conductive particles can include graphite particles, metal sulfide such as molybdenum sulfide, tungsten sulfide, titanium sulfide, copper sulfide, zinc sulfide, etc. or a combination thereof. The particles can have a number average particle size of about 0.1 to about 500 μm, preferably about 0.5 to about 100 μm, more preferably about 0.5 to about 10 μm.

The organic solvent in the coating composition can include at least one of an alcohol, an amine, an amide, an ether, an ester, a ketone, acetonitrile, dimethylsulfoxide, or an aromatic solvent such as toluene and xylenes. The solvent can be removed after the coating composition is deposited on the internal surface of the tubular member.

The concentration of the solvent can be from 25 to about 80 volume percent, or about 33 to about 67 volume percent, based on a total volume of the coating composition. The concentration of the electrically conductive or semi-conductive particles can be about 2 to about 80 weight percent, or about 30 to about 70 weight percent, based on a total weight of the coating composition. In an aspect, the formed polymer sublayer comprises about 10 to about 80 wt %, about 30 wt % to about 70 wt % or about 40 to about 60 weight percent of the electrically conductive or semi-conductive particles, and about 20 wt % to about 90 wt %, about 30 wt % to about 70 wt %, or about 40 wt % to about 60 wt % of the polymer comprising at least one of an epoxy, a phenolic resin, or an epoxy phenolic resin, each based on a total weight of the polymer sublayer.

The thickness of the polymer sublayer can be about 1 μm to about 50 μm, preferably about 5 μm to about 25 μm, more preferably about 5 μm to about 10 μm.

The DLC sublayer can be formed via a plasma-assisted chemical vapor deposition (CVD) process as described herein in the context of forming the hydrophobic layer. The DLC sublayer can comprise an undoped DLC material. The DLC sublayer can be formed from a precursor composition comprising or consisting of methane (CH₄) and/or acetylene (C₂H₂) gas without any dopant precursor. The DLC sublayer can have a thickness of about 0.1 to about 1 μm, preferably about 0.25 to about 0.75 μm.

The hydrophobic layer can be deposited on the chromium, polymer, or DLC sublayer via plasma-assisted chemical vapor deposition. The precursor composition for the hydrophobic layer can include (1) a silicon dopant precursor and (2) methane (CH₄) and/or acetylene (C₂H₂) gas. The silicon dopant precursor can include at least one of tetra-ethoxysilane (TEOS), tetramethoxysilane (TMOS), hexamethyldisiloxane (HMDSO) or hexamethyldisilazane (HMDS). HMDSO is a liquid at room temperature, and it has a boiling point of 100.5° C. at 1 atm and a vapor pressure of about 4400 Pascals (Pa) at 20° C. The HMDSO is a preferable silicon dopant precursor as it evaporates under the coating operating pressure. The precursor composition may form a plasma by itself or optionally with the assistance of a carrier gas such as argon, nitrogen, or a combination thereof. To add fluorine dopant, the precursor composition can further include at least one of tetrafluoromethane, or difluoroacetylene. To add other doping elements such as Co, Cr, W and Ti, the precursor composition can also include metal carbonyls W(CO)₆, Mo(CO)₆, Cr(CO)₆, Co₂(CO)₈, (C₅H₅)₂Ti(CO)₂, metal halides WF₆, CrF₅, or a combination thereof. If used, a volume ratio of the precursor composition relative to the carrier gas is about 20:1 to about 1:20, or about 10:1 to about 1:10.

Before the deposition, a vacuum can be created in the interior volume of the tubular member defined by the internal surface to a pressure of 0.01 to about 10 Pa or about 0.1 to about 5 Pa. To create the vacuum, the tubular member can be placed in a vacuum chamber. If the tubular member cannot fit inside a vacuum chamber, the vacuum can be created using a pump connected to the tubular member, for example connected to one end or both ends of the tubular member. More than one pump can be used.

Then the precursor composition and the optional carrier gas can be supplied into the interior volume of the tubular member. A manifold disposed inside the interior volume of the tubular member along the longitudinal direction can be used to introduce the precursor composition and the optional carrier gas to the interior volume of the tubular member. The manifold can be perforated to provide a uniform distribution of the gas flow over the sublayer coated on the internal surface of the tubular member. The manifold can also serve as an electrode at the ground potential. The flow rate of CH₄ and/or C₂H₂ gas can be about 0.1 to about 1000 cm³/min, preferably about 1 to about 500 cm³/min. The flow rate of the dopant precursor such as HMDSO can range from about 0.1 to about 500 cm³/min, preferably from about 0.5 to about 300 cm³/min. A heater or evaporator can be added to control the gas flow rate, especially for the precursors that have a higher boiling point or lower evaporating pressure at room temperature.

The hydrophobic layer is deposited at a temperature of about room temperature to about 200° C., preferably about room temperature to about 100° C., more preferably about room temperature to about 50° C.

The energy to start the decomposition of the precursor composition is supplied by the plasma. To initiate deposition of the hydrophobic layer on the sublayer, a plasma is formed in the interior volume of the tubular member from the precursor composition and the optional carrier gas. The plasma pressure is about 0.1 to about 100 Pa or about 0.1 to about 10 Pa. Pumps can be used to maintain the pressure during the deposition. In an aspect, the plasma is generated from the precursor composition and the optional carrier gas by electrically exciting the tubular member through negatively biasing the tubular member with a pulsed voltage in the range of about −0.1 to about −10 kilovolt (kV), preferably about −0.3 to about −8 kV, relative to a ground at a pulse frequency of <20,000 hertz (Hz), preferably about 500 to about 5000 Hz, and a pulse width ranging from about 0.01 to about 50 microseconds (ms). The pulse voltage can be provided by a pulsed DC power supply electrically connected to the tubular member.

The deposition time may range from about 5 to about 240 minutes, preferably about 10 to about 120 minutes or about 15 to about 60 minutes.

The formed hydrophobic layer can include a doped DLC material, for example, an amorphous DLC doped with Si and optionally at least one of F, Co, Cr, W, or Ti. Preferably, the doped DLC material in the hydrophobic layer is doped with about 20 to about 35 atomic percent or about 30 atomic percent of Si. The amount of the dopant can be controlled by the volume ratio of CHA/HMDSO or C₂H₂/HMDSO. The volume ratio is between 0 to about 30, or from greater than 0 to about 30. Optionally, the doped DLC material in the hydrophobic layer further comprises about 15 to about 25 atomic percent of hydrogen atoms.

The doped DLC material in the hydrophobic layer can comprise about 50 to about 90 atomic percent or about 60 to about 70 atomic percent of sp² bonded carbon and about 10 to about 50 atomic percent or about 30 to about 40 atomic percent of sp³ bonded carbon. As used herein, “sp² bonded carbon” refers to carbon atoms bonded to neighboring carbon atoms in a crystal structure substantially corresponding to the graphite isotope of carbon. “Sp³ bonded carbon” refers to carbon atoms bonded to neighboring carbon atoms in a crystal structure substantially corresponding to the diamond isotope of carbon.

The sp² and sp³ bonded carbon can be uniformly distributed in the hydrophobic layer or be present in a gradient. For example, a relative atomic ratio of sp² and sp³ bonded carbon in the hydrophobic layer can decrease in a direction from the sublayer to an outer surface of the hydrophobic layer. The relative atomic ratio of sp² and sp³ bonded carbon can be controlled by changing bias voltage, changing the precursor gas, or a combination thereof. For example, adding nitrogen in the precursor gas facilitates the formation of N—H, C═N, C≡N bonds, which in turn decreases the fraction of sp³ carbon bonds, and/or obstructs the carbon-carbon cross links. In an aspect, the method further comprises controlling or reducing an amount of the nitrogen in the precursor composition so that a relative atomic ratio of sp² and sp³ bonded carbon in the hydrophobic layer decreases in a direction from the sublayer to an outer surface of hydrophobic layer.

Optionally, the method further includes forming an intermediate layer between the sublayer and the hydrophobic layer. The intermediate layer can comprise an undoped DLC material or a second DLC material doped with less silicon than the doped DLC material in the hydrophobic layer. The intermediate layer is formed without using HMDSO in the precursor gas or by reducing the concentration of HMDSO to less than 50% or less than 25% as compared to the HMDSO used in forming the hydrophobic layer. The intermediate layer can have a thickness of about 0.1 to about 1 μm, preferably about 0.25 to about 0.75 μm.

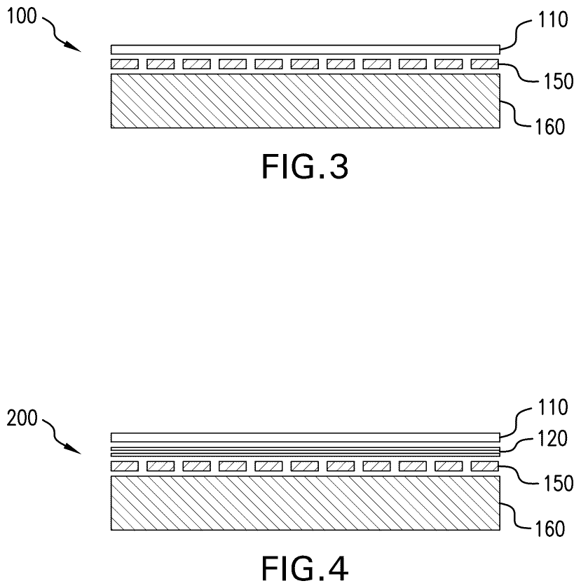

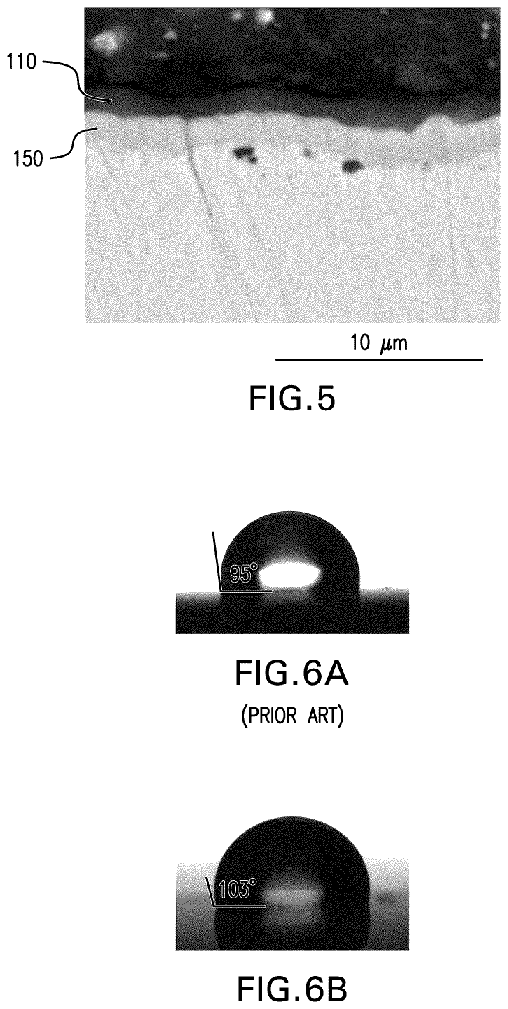

The method disclosed herein can produce a tubular member having an internal surface coated with a multi-layer coating having a sublayer disposed on the internal surface and a hydrophobic layer disposed on the sublayer. As illustrated in FIGS. 3-5, the tubular member (100, 200) has a substrate (160) having an internal surface and a coating disposed on the internal surface, where the coating comprises a chromium, polymer, or DLC sublayer (150) disposed on the internal surface of the tubular member and a hydrophobic layer (110) disposed on the sublayer (150). The coating can further include an intermediate layer (120) between the hydrophobic layer (110) and the sublayer (150). The intermediate layer (120) can include a second DLC material which is different from the doped DLC material in the hydrophobic layer (110).

The material for forming the internal surface of the tubular member is not particularly limited and can include metals such as iron, chromium, nickel, titanium, cobalt, or alloys thereof, or combinations thereof. In an embodiment, the substrate comprises steel and nickel based alloys. The internal surface can have a contoured shape. The tubular member can have an aspect ratio (length/internal diameter) of greater than 1.

The coating can have a thickness of about 2 to about 5 micrometers. Preferably the coating has a thickness of about 3 to about 5 micrometers.

With a chromium, polymer, or DLC sublayer, the multi-layer coating can have improved properties such as improved hydrophobicity or anti-scaling performance, improved galling or wearing resistance, and/or enhanced corrosion or erosion resistance as compared to a DLC coating without any sublayer.

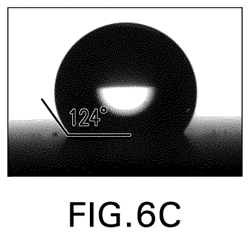

FIGS. 6A-6C compare the contact angle (degree) of a DLC coating without any sublayer, a coating including a DLC layer disposed on a dense chromium sublayer, and a coating including a DLC layer disposed on a polymer sublayer. The results show that when coating has a sublayer as disclosed herein, the hydrophobicity of the coating can be greatly increased. For example, the sublayer can increase the hydrophobicity of the coating by greater than 30%, greater than 40%, or even greater than 50%, as determined by comparing the contact angle of water with the coating on a surface without any sublayer and the contact angle of water with the same DLC on a surface with a sublayer.

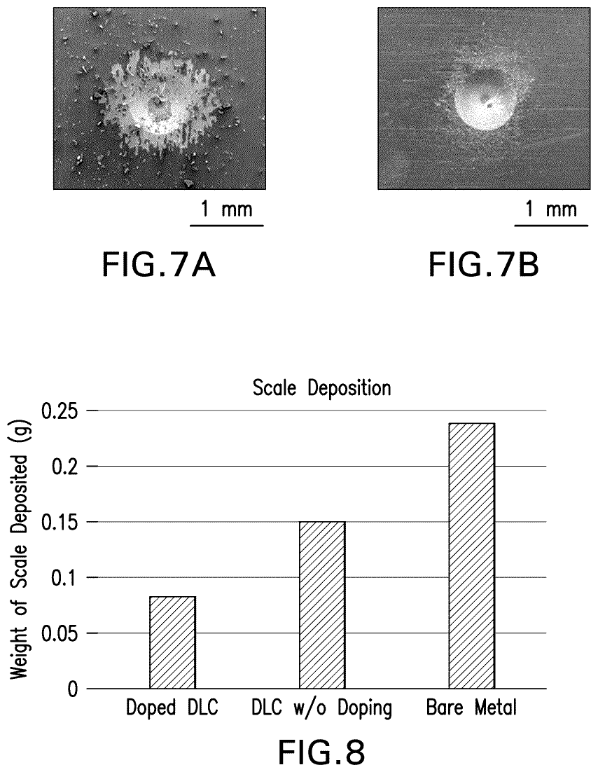

In a further advantageous feature, the coating with the sublayer has excellent bond strength. As shown in FIG. 7A and FIG. 7B, the coating with the sublayer as disclosed herein has improved bonding strength with an internal surface of the tubular member determined in accordance with VDI 3198 when the indentation test is conducted in accordance with ASTM E18.

When the hydrophobic layer comprises a doped DLC material as disclosed herein, the coating can also have improved anti-scaling property as compared to a coating with undoped DLC or a bare metal without any coating as shown in FIG. 8.

Set forth are various aspects of the disclosure.
Aspect 1. A method of coating an internal surface of a tubular member, the method comprising: forming a sublayer on the internal surface of the tubular member, the sublayer comprising a chromium sublayer, a polymer sublayer comprising electrically conductive or semi-conductive particles, or a DLC sublayer comprising an undoped DLC material; disposing a hydrophobic layer on the sublayer via a plasma-assisted chemical deposition thereby forming a coating on the internal surface of the tubular member, the hydrophobic layer comprising a doped DLC material, and the doped DLC material comprising an amorphous DLC doped with Si and optionally at least one of F, Co, Cr, W, or Ti.
Aspect 2. The method as in any prior aspect, wherein the coating has a thickness of about 1 micron to about 5 microns.
Aspect 3. The method as in any prior aspect, further comprising forming the chromium sublayer by electrochemical deposition.
Aspect 4. The method as in any prior aspect, wherein the electrochemical deposition comprises exposing the internal surface of the tubular member to a chromium electrolytic solution comprising chromic acid and a catalyst at a temperature of about room temperature to about 65° C.
Aspect 5. The method as in any prior aspect, wherein the chromium sublayer has a thickness of about 2.5 to about 7.5 microns.
Aspect 6. The method as in any prior aspect, wherein the chromium sublayer has a porosity of less than 1%.
Aspect 7. The method as in any prior aspect, wherein the chromium sublayer has a textured surface comprising nodules.
Aspect 8. The method as in any prior aspect, further comprising forming the polymer sublayer by dip coating, air spray coating, or airless spray coating.
Aspect 9. The method as in any prior aspect, wherein the polymer sublayer has a thickness of about 2.5 to about 12.5 micron.
Aspect 10. The method as in any prior aspect, wherein the polymer sublayer comprises at least one of an epoxy, a phenolic resin, or an epoxy phenolic resin.
Aspect 11. The method as in any prior aspect, wherein the electrically conductive or semi-conductive particles comprise at least one of graphite particles, or metal sulfide particles.
Aspect 12. The method as in any prior aspect, wherein the electrically conductive or semi-conductive particles in the polymer sublayer are present in an amount of about 10 wt % to about 80 wt % based on a total weight of the polymer sublayer.
Aspect 13. The method as in any prior aspect, further comprising forming the DLC sublayer by a plasma-assisted chemical deposition process using a precursor composition comprising or consisting of at least one of methane or acetylene, without a dopant precursor.
Aspect 14. The method as in any prior aspect, wherein the hydrophobic layer is formed from a precursor composition comprising a silicon dopant precursor and at least one of methane or acetylene.
Aspect 15. The method as in any prior aspect, wherein the precursor composition further comprises nitrogen, and the method further comprises controlling or reducing an amount of the nitrogen in the precursor composition so that a relative atomic ratio of sp² and sp³ bonded carbon in the hydrophobic layer decreases in a direction from the sublayer to an outer surface of hydrophobic layer.
Aspect 16. The method as in any prior aspect, further comprising forming an intermediate layer between the hydrophobic layer and the sublayer, and the intermediate layer comprising an intermediate DLC material different from the doped DLC material in the hydrophobic layer.
Aspect 17. The method as in any prior aspect, wherein the intermediate layer is formed by adjusting an amount of a silicon dopant precursor to less than 50% percent of the silicon dopant precursor used in forming the hydrophobic coating.
Aspect 18. The method as in any prior aspect, wherein the tubular member has an aspect ratio of greater than 1.
Aspect 19. A tubular member having a coated internal surface, the tubular member comprising: an internal surface; and a coating disposed on the internal surface, the coating comprising a sublayer disposed on the internal surface of the tubular member, the sublayer comprising a chromium sublayer, a polymer sublayer comprising electrically conductive or semi-conductive particles, or a DLC sublayer comprising an undoped DLC material; and a hydrophobic layer disposed on the sublayer, the hydrophobic layer comprising a doped DLC material, which is an amorphous DLC doped with about 20 to about 35 atomic percent of silicon, wherein the coating has a thickness of about 1 micron to about 5 microns.
Aspect 20. The tubular member as in any prior aspect, wherein the sublayer is a chromium sublayer, and the chromium sublayer has a porosity of less than 1%.
Aspect 21. The tubular member as in any prior aspect, wherein the sublayer is polymer layer comprising at least one of an epoxy, a phenolic resin, or an epoxy phenolic resin, and the electrically conductive or semi-conductive particles comprise at least one of graphite particles, alumina particles, or silicon carbide particles.
Aspect 22. The tubular member as in any prior aspect, wherein the coating further comprises an intermediate layer disposed between the hydrophobic layer and the sublayer, and the intermediate layer comprises an intermediate DLC material having less silicon than the doped DLC material in the hydrophobic layer.

All ranges disclosed herein are inclusive of the endpoints, and the endpoints are independently combinable with each other. As used herein, “combination” is inclusive of blends, mixtures, alloys, reaction products, and the like. All references are incorporated herein by reference.

The use of the terms “a” and “an” and “the” and similar referents in the context of describing the invention (especially in the context of the following claims) are to be construed to cover both the singular and the plural, unless otherwise indicated herein or clearly contradicted by context. The modifier “about” used in connection with a quantity is inclusive of the stated value and has the meaning dictated by the context (e.g., it includes the degree of error associated with measurement of the particular quantity). In an embodiment, the term “about” means that the value associated with about can vary by 10%. As used herein, size means largest dimension. Unless defined otherwise, technical and scientific terms used herein have the same meaning as is commonly understood by one of skill in the art to which this invention belongs.

All references cited herein are incorporated by reference in their entirety. While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

What is claimed is:

1. A method of coating an internal surface of a tubular member, the method comprising:
forming a sublayer on the internal surface of the tubular member, the sublayer comprising a chromium sublayer, a polymer sublayer comprising electrically conductive or semi-conductive particles, or a diamond-like carbon sublayer comprising an undoped diamond-like carbon material;
disposing a hydrophobic layer on the sublayer via a plasma-assisted chemical deposition thereby forming a coating on the internal surface of the tubular member, the hydrophobic layer comprising a doped diamond-like carbon material, and the doped diamond-like carbon material comprising an amorphous diamond-like carbon doped with Si and optionally at least one of F, Co, Cr, W, or Ti.

2. The method of claim 1, wherein the coating has a thickness of about 1 micron to about 5 microns.

3. The method of claim 1, further comprising forming the chromium sublayer by electrochemical deposition.

4. The method of claim 3, wherein the electrochemical deposition comprises exposing the internal surface of the tubular member to a chromium electrolytic solution comprising chromic acid and a catalyst at a temperature of about room temperature to about 65° C.

5. The method of claim 3, wherein the chromium sublayer has a thickness of about 2.5 to about 7.5 microns.

6. The method of claim 1, wherein the chromium sublayer has a porosity of less than 1%.

7. The method of claim 1, wherein the chromium sublayer has a textured surface comprising nodules.

8. The method of claim 1, further comprising forming the polymer sublayer by dip coating, air spray coating, or airless spray coating.

9. The method of claim 8, wherein the polymer sublayer has a thickness of about 2.5 to about 12.5 micron.

10. The method of claim 8, wherein the polymer sublayer comprises at least one of an epoxy, a phenolic resin, or an epoxy phenolic resin.

11. The method of claim 8, wherein the electrically conductive or semi-conductive particles comprise at least one of graphite particles, or metal sulfide particles.

12. The method of claim 8, wherein the electrically conductive or semi-conductive particles in the polymer sublayer are present in an amount of about 10 wt % to about 80 wt % based on a total weight of the polymer sublayer.

13. The method of claim 1, further comprising forming the diamond-like carbon sublayer by a plasma-assisted chemical deposition process using a precursor composition comprising at least one of methane or acetylene, without a dopant precursor.

14. The method of claim 1, wherein the hydrophobic layer is formed from a precursor composition comprising a silicon dopant precursor and at least one of methane or acetylene.

15. The method of claim 14, wherein the precursor composition further comprises nitrogen, and the method further comprises reducing an amount of the nitrogen in the precursor composition so that a relative atomic ratio of sp² and sp³ bonded carbon in the hydrophobic layer decreases in a direction from the sublayer to an outer surface of hydrophobic layer.

16. The method of claim 1, further comprising forming an intermediate layer between the hydrophobic layer and the sublayer, and the intermediate layer comprising an intermediate diamond-like carbon material different from the doped diamond-like carbon material in the hydrophobic layer.

17. The method of claim 16, wherein the intermediate layer is formed by adjusting an amount of a silicon dopant precursor to less than 50% percent of the silicon dopant precursor used in forming the hydrophobic coating.

18. A tubular member having a coated internal surface, the tubular member comprising:
an internal surface; and
a coating disposed on the internal surface,
the coating comprising
a sublayer disposed on the internal surface of the tubular member, the sublayer comprising a chromium sublayer, a polymer sublayer comprising electrically conductive or semi-conductive particles, or a diamond-like carbon sublayer comprising an undoped diamond-like carbon material; and
a hydrophobic layer disposed on the sublayer, the hydrophobic layer comprising a doped diamond-like carbon material, which is an amorphous diamond-like carbon doped with about 20 to about 35 atomic percent of silicon,
wherein the coating has a thickness of about 1 micron to about 5 microns.

19. The tubular member of claim 18, wherein the sublayer is a chromium sublayer, and the chromium sublayer has a porosity of less than 1%.

20. The tubular member of claim 18, wherein the sublayer is polymer layer comprising at least one of an epoxy, a phenolic resin, or an epoxy phenolic resin, and the electrically conductive or semi-conductive particles comprise at least one of graphite particles, alumina particles, or silicon carbide particles.

21. The tubular member of claim 18, wherein
the coating further comprises an intermediate layer disposed between the hydrophobic layer and the sublayer, and
the intermediate layer comprises an intermediate diamond-like carbon material having less silicon than the doped diamond-like carbon material in the hydrophobic layer.
